(19) United States
(12) Patent Application Publication
(10) Pub. No.: US 2025/0111959 A1
(43) Pub. Date: Apr. 3, 2025

(54) APPARATUS AND METHOD FOR ELECTROMAGNETIC RADIATION SHIELDING

(71) Applicants: SHAWN POLLARD, MEMPHIS, TN (US); FIROUZEH SABRI, LAKELAND, TN (US)

(72) Inventors: SHAWN POLLARD, MEMPHIS, TN (US); FIROUZEH SABRI, LAKELAND, TN (US)

(21) Appl. No.: 18/905,008

(22) Filed: Oct. 2, 2024

Related U.S. Application Data
(60) Provisional application No. 63/541,916, filed on Oct. 2, 2023.

(51) Int. Cl. G21F 1/08; G02B 5/20; H05K 9/00

(52) U.S. Cl. CPC G21F 1/08; G02B 5/208; H05K 9/0088

(57) ABSTRACT

A multilayer substrate with coating that provides selective radiation shielding along with antifouling and antistatic capabilities. The substrates are customizable (e.g., lightweight, thin, flexible or rigid, robust, and may or may not be porous), and coated with a smooth, magnetic alloy as a blocking material for medium to high energy charged particle radiation and electromagnetic interference shielding. In one example, the substrate is a lightweight, flexible, and transparent substrate such as an aerogel, μm-thin flexible ceramic, or siloxane-based space-qualified polymers, coated with a a thin nickel-iron alloy based ferromagnetic film as an absorption media for medium to high energy charged article radiation as well as electromagnetic interference (EMI) shielding.

This application claims benefit of and priority to U.S. Provisional App. No. 63/541,916, filed Oct. 2, 2023, which is incorporated herein in its entirety by specific reference for all purposes.

### FIELD OF INVENTION

This invention relates to an apparatus, system, and related methods for enhanced electromagnetic (EM) shielding.

### BACKGROUND OF INVENTION

Electromagnetic radiation has been regarded as an increasing hazard for commercial devices, biological systems, defense, and information technologies. This is also a major concern for long distanced manned missions and the safety of astronauts. This is a result of their ability to instigate noise known as electromagnetic interference. Electromagnetic interference noise can lead +to faults in the operation of modern devices (for example, soft errors in integrated circuits) and to information leakage, as well as introducing novel security concerns in the aerospace industry. It also has been recently viewed as a potential health hazard.

Charged particle radiation exposure provides another challenge, with similar results: e.g., soft errors in electron devices, cellular damage, and increased cancer rates.

As a results, shielding materials and devices have grown into a multi-billion dollar industry. Current shielding technologies, however, afford several key drawbacks. More specifically, the majority of shielding devices on the market are composed of metallic conductors that lack flexibility. In addition, these devices typically have high masses and high costs due to the common materials used (i.e., Ag and Ag-alloys), and their single use/permanent nature. Furthermore, these traditional metallic materials lack easy monitoring of exposure and degradation over time, making failure prediction and total dose monitoring impractical.

Accordingly, what is needed is a shielding material that is flexible, lightweight, low-cost, and reusable, and that can be monitored in a non-destructive, remote manner allowing for failure prediction and dose monitoring while maintaining robust corrosion resistance.

### SUMMARY OF INVENTION

Reduction and/or prevention of exposure to radiation (e.g., ionizing, non-ionizing, cosmic, etc.) is critical in many industries, most notably healthcare, aerospace, and the auto (both EV and combustion engine) manufacturing industries. The invention comprises customizable substrates (lightweight, thin, flexible or rigid robust, porous or non-porous) coated with a smooth, magnetic alloy as a blocking material for medium to high energy charged particle radiation and electromagnetic interference shielding. This coating also experiences dose dependent changes to magnetic properties which may be measured through non-destructive remote sensing methods to afford total dose monitoring at points of potential exposure. The proposed technology goes beyond a superficial coating and can be designed such that the magnetic fingerprint is spread throughout the bulk of the material, leading to enhanced shielding. The invention can be utilized over a broad range of temperatures, cryogenics to 1000 C. The substrate may be modified in order to influence the magnetic properties of the thin film.

Thus, in various exemplary embodiments, the present invention comprises a unique material/substrate combination which allows for flexible, lightweight, reusable and low-cost materials that can be monitored in a non-destructive, remote manner allowing for failure prediction and dose monitoring while maintaining robust corrosion resistance. More specifically, it provides selective radiation shielding capabilities combined with antifouling and antistatic capabilities.

In several embodiments, the invention comprises a bi-layer or multilayer structure comprising a lightweight, flexible, transparent, substrate (including, but not limited to, aerogels, um-thin flexible ceramics, and siloxane-based space-qualified polymers) coated with a thin nickel-iron alloy based ferromagnetic film as an absorption media for medium to high energy charged particle radiation as well as electromagnetic interference (EMI) shielding. The magnetic film is grown through DC-magnetron sputtering of permalloy (Ni₈₀Fe₂₀) and co-sputtering to alloy permalloy with dilute amounts of other metallic layers to further enhance corrosion resistance (i.e. Mo, Ru, W), and can be designed such that the magnetic alloy is impregnated into the bulk of the host material, as shown in the figure, leading to enhanced shielding effects, as well as patterned into desired geometries dependent on the application. Monitoring of magnetic properties is done non-locally through measurements of the Kerr or Faraday effects (shown in the figures), providing a means to monitor the film integrity and exposure in a non-destructive manner, even in corrosive environments. The substrate can be prepared using sol-gel processes and dried under supercritical conditions. In another form, the substrate can be prepared by means of crosslinking and curing at room temperature. An interfacial layer to enhance bonding may be included for some applications. Furthermore, full encapsulation of the entire entity will be considered for applications in aerospace.

The invention includes three distinct aspects: (1) shielding and sensing combined into one device; (2) usage of fully cured and crosslinked substrates to serve as the platform for the magnetically active layer; and (3) combining other sensing forms (such as temperature and shock) with magnetic sensing capabilities. The invention is the creation of a robust multifunctional platform that combines sensing thin films with porous, flexible, transparent, and inert 3-D materials, to provide a low-cost light-weight alternative to expensive, rigid, heavy, and single-use shielding technologies currently used.

The invention may be used to temporarily or permanently provide EM shielding through the encapsulation or enclosure at the desired location. The invention is removable, reusable, and non-invasive. It can be sized to the final shape and geometry desired by the end user. For example, a cube-shaped sensor can be placed adjacent to the electrical control units of electric and hybrid vehicles, to protect from interference.

### BRIEF DESCRIPTION OF THE FIGURES

FIG. 1 shows a cross-section of a multilayer material in accordance with an exemplary embodiment of the present invention.

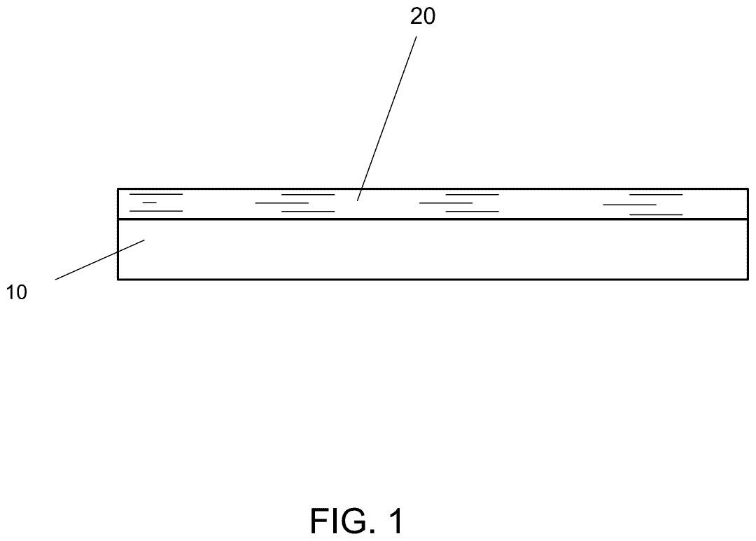

FIG. 2 shows an alternative embodiment of the multilayer material of FIG. 1.

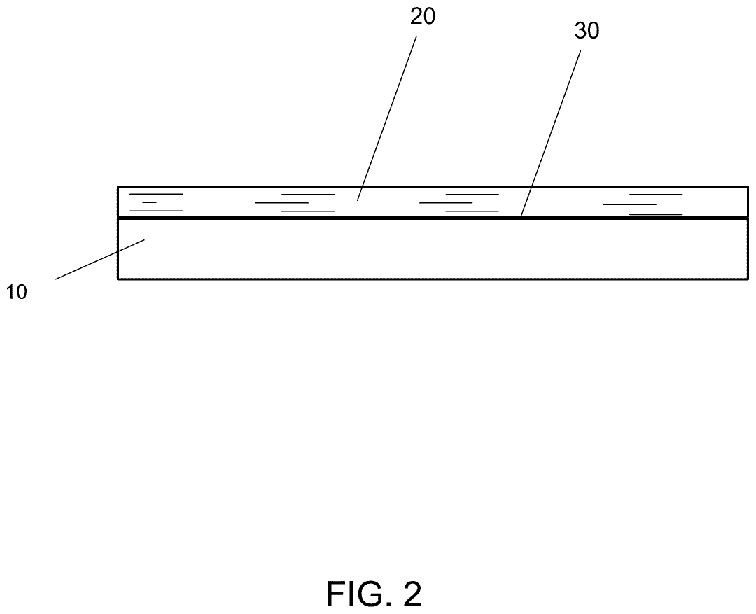

### DETAILED DESCRIPTION OF EXEMPLARY EMBODIMENTS

Reduction and/or prevention of exposure to radiation (e.g., ionizing, non-ionizing, cosmic, etc.) is critical in many industries, most notably healthcare, aerospace, and the auto (both EV and combustion engine) manufacturing industries. The invention comprises customizable substrates 10 (lightweight, thin, flexible or rigid robust, porous or non-porous) coated with a smooth, magnetic alloy as a blocking material for medium to high energy charged particle radiation and electromagnetic interference shielding. This coating 20 also experiences dose dependent changes to magnetic properties which may be measured through non-destructive remote sensing methods to afford total dose monitoring at points of potential exposure. The proposed technology goes beyond a superficial coating and can be designed such that the magnetic fingerprint is spread throughout the bulk of the material, leading to enhanced shielding. The invention can be utilized over a broad range of temperatures, cryogenics to 1000 C. The substrate may be modified in order to influence the magnetic properties of the thin film.

Thus, in various exemplary embodiments, the present invention comprises a unique material/substrate combination which allows for flexible, lightweight, reusable and low-cost materials that can be monitored in a non-destructive, remote manner allowing for failure prediction and dose monitoring while maintaining robust corrosion resistance. More specifically, it provides selective radiation shielding capabilities combined with antifouling and antistatic capabilities.

In several embodiments, the invention comprises a bi-layer or multilayer structure comprising a lightweight, flexible, transparent, substrate 10 (including, but not limited to, aerogels, um-thin flexible ceramics, and siloxane-based space-qualified polymers) coated with a thin nickel-iron alloy based ferromagnetic film 20 as an absorption media for medium to high energy charged particle radiation as well as electromagnetic interference (EMI) shielding. The magnetic film is grown through DC-magnetron sputtering of permalloy (Ni₈₀Fe₂₀) and co-sputtering to alloy permalloy with dilute amounts of other metallic layers to further enhance corrosion resistance (i.e. Mo, Ru, W), and can be designed such that the magnetic alloy is impregnated into the bulk of the host material, as shown in the figure, leading to enhanced shielding effects, as well as patterned into desired geometries dependent on the application. Monitoring of magnetic properties is done non-locally through measurements of the Kerr or Faraday effects (shown in the figures), providing a means to monitor the film integrity and exposure in a non-destructive manner, even in corrosive environments. The substrate can be prepared using sol-gel processes and dried under supercritical conditions. In another form, the substrate can be prepared by means of crosslinking and curing at room temperature. An interfacial layer to enhance bonding may be included for some applications. Furthermore, full encapsulation of the entire entity will be considered for applications in aerospace.

The invention includes three distinct aspects: (1) shielding and sensing combined into one device; (2) usage of fully cured and crosslinked substrates to serve as the platform for the magnetically active layer; and (3) combining other sensing forms (such as temperature and shock) with magnetic sensing capabilities. The invention is the creation of a robust multifunctional platform that combines sensing thin films with porous, flexible, transparent, and inert 3-D materials, to provide a low-cost light-weight alternative to expensive, rigid, heavy, and single-use shielding technologies currently used.

The invention may be used to temporarily or permanently provide EM shielding through the encapsulation or enclosure at the desired location. The invention is removable, reusable, and non-invasive. It can be sized to the final shape and geometry desired by the end user. For example, a cube-shaped sensor can be placed adjacent to the electrical control units of electric and hybrid vehicles, to protect from interference.

The present invention offers an improvement to existing shielding technologies in several ways. First, the invention combines multiple types of sensing and shielding capabilities, with a focus on EM shielding. Other sensing needs can be added as desired. The proposed invention also is more cost-effective and versatile compared to existing techniques for shielding and sensing. The invention utilizes advanced state of the art coating techniques to deposit thin continuous films of magnetically active layers, on substrates that are intended for high performance under extreme conditions including flexible ceramics, aerogels, and siloxane-based polymers. The invention also may include an adhesion promoting layer 30 and technique to enhance stability of the multilayer.

In sum, the present invention combines light-weight materials with low-cost magnetic films that can be monitored for exposure and degradation in a non-destructive manner. Further, by allowing for the impregnation of the shielding material into a matrix, enhanced shielding effects from a much-reduced mass of materials allows for shielding with significantly less total mass, while maintaining corrosion resistance, essential for aerospace and EV applications. The invention further includes a novel technique for promoting adhesion and stability of the multilayer, and a novel technique for sensing, and shielding of EM radiation. The invention offers multi-sensing capabilities that can be customized based on the industry needs.

Supporting data and information for the above-described invention and various exemplary embodiments are described in detail in the attached Appendix materials, which are attached hereto and incorporated herein in their entireties (including all text and figures therein) by specific reference for all purposes.

Thus, it should be understood that the embodiments and examples described herein have been chosen and described in order to best illustrate the principles of the invention and its practical applications to thereby enable one of ordinary skill in the art to best utilize the invention in various embodiments and with various modifications as are suited for particular uses contemplated. Even though specific embodiments of this invention have been described, they are not to be taken as exhaustive. There are several variations that will be apparent to those skilled in the art.

What is claimed is:

1. A system for enhanced electromagnetic shielding, comprising:
a multi-layer shielding material comprising
a flexible substrate with a first side and a second side;
a ferromagnetic film disposed on at least the first side, the ferromagnetic film comprising a nickel-iron alloy.

2. The system of claim 1, wherein the flexible substrate is transparent.

3. The system of claim 1, wherein the flexible substrate comprises polydimethysiloxane (PDMS).

4. The system of claim 1, wherein the flexible substrate comprises a polyurea crosslinked silica aerogels (PCSA).

5. The system of claim 1, wherein the flexible substrate comprises a polyurethane aerogel.

6. The system of claim 1, wherein the flexible substrate comprises a superelastic shape memory polyurethane aerogel.

7. The system of claim 1, wherein the flexible substrate comprises a Yttria-Stabilized Zirconia (YSZ) ceramic sheet.

8. The system of claim 1, wherein the ferromagnetic film comprises permalloy (Ni₈₀Fe₂₀, Py).

9. The system of claim 1, wherein the ferromagnetic film comprises patterned permalloy (Ni₈₀Fe₂₀, Py).

10. The system of claim 1, wherein the ferromagnetic film is a sputtered permalloy.

11. The system of claim 5, wherein the ferromagnetic film has a thickness ranging from approximately 5nm to approximately 100 nm.

12. The system of claim 5, wherein the ferromagnetic film has a thickness ranging from approximately 50 nm to approximately 100 nm.

13. The system of claim 5, wherein the ferromagnetic film has a thickness of 50 nm.

14. The system of claim 5, wherein the ferromagnetic film has a thickness of 10 nm.

15. The system of claim 1, wherein the multi-layer shielding material blocks transmission of UVB and UVC radiation, while allowing optical transmission on the flexible substrate.

16. The system of claim 1, wherein the multi-layer shielding material absorbs charged particle radiation.

17. The system of claim 1, wherein the multi-layer shielding material is an electromagnetic interference shielding material.

18. The system of claim 1, wherein the multi-layer shielding material blocks transmission of UVB and UVC radiation, while allowing optical transmission on the flexible substrate.

19. The system of claim 8, wherein the permalloy is alloyed with one or more additional metallic layers.

20. The system of claim 19, wherein the one or more additional metallic layers comprise one or more of Mo, Ru, or W.

21. The system of claim 8, wherein the permalloy impregnates, in whole or in part, the flexible substrate.

22. The system of claim 1, wherein the multi-layer shielding material further comprises a sensor.
